(19) United States
(12) Patent Application Publication
(10) Pub. No.: US 2014/0175521 A1
(43) Pub. Date: Jun. 26, 2014

(54) SOLID-STATE IMAGE PICKUP DEVICE, METHOD OF MANUFACTURING SOLID-STATE IMAGE PICKUP DEVICE, AND ELECTRONIC APPARATUS

(71) Applicant: Sony Corporation, Tokyo (JP)

(72) Inventor: Yuki Miyanami, Kanagawa (JP)

(73) Assignee: Sony Corporation, Tokyo (JP)

(21) Appl. No.: 14/133,286

(22) Filed: Dec. 18, 2013

(30) Foreign Application Priority Data
Dec. 25, 2012 (JP) 2012-281394

(51) Int. Cl. H01L 27/146

(52) U.S. Cl. CPC H01L 27/14643; H01L 27/14689
USPC 257/231; 438/59; 257/292

(57) ABSTRACT

A solid-state image pickup device, includes: a semiconductor substrate; a semiconductor layer of a first conductivity type formed in the semiconductor substrate and formed for each pixel; a solid-phase diffusion layer of a second conductivity type formed in a surface portion of the semiconductor substrate, the solid-phase diffusion layer facing the semiconductor layer; and an oxide film containing an impurity element of the second conductivity type and formed by an atomic layer deposition method.

### CROSS REFERENCE TO RELATED APPLICATIONS

This application claims the benefit of Japanese Priority Patent Application JP 2012-281394 filed on Dec. 25, 2012, the entire contents of which are incorporated herein by reference.

### BACKGROUND

The present disclosure relates to a solid-state image pickup device, for example, having a photodiode in a semiconductor substrate, to a method of manufacturing such a solid-state image pickup device, and to an electronic apparatus.

A solid-state image pickup device such as a CCD (Charge-Coupled Device) and a CMOS (Complementary Metal Oxide Semiconductor) image sensor has a plurality of pixels that are arranged two-dimensionally, wherein each of the pixels is provided with a photodiode and a plurality of transistors. A predetermined voltage pulse is applied to each of the plurality of transistors, and thereby, a signal current is read out.

In such a solid-state image pickup device, a photodiode is formed within a semiconductor substrate made of silicon (Si) etc., and a so-called HAD (Hole Accumulation Diode) structure has been proposed that carries out a shallow ion implantation with the inverse conductivity type of that of a charge storage layer (photoelectric conversion layer) in the vicinity of the uppermost surface of this silicon (see Japanese Unexamined Patent Application Publication No. 2004-273640).

### SUMMARY

According to the HAD structure as described above, it is possible to suppress occurrence of dark current by recombining electrons, generated in an interface state in the vicinity of an interface of silicon, to holes. It is desired to achieve such an HAD structure utilizing any other method.

It is desirable to provide a solid-state image pickup device capable of forming the HAD structure to suppress occurrence of dark current, a method of manufacturing such a solid-state image pickup device, and an electronic apparatus.

According to an embodiment of the present disclosure, there is provided a solid-state image pickup device, including: a semiconductor substrate; a semiconductor layer of a first conductivity type formed in the semiconductor substrate and formed for each pixel; a solid-phase diffusion layer of a second conductivity type formed in a surface portion of the semiconductor substrate, the solid-phase diffusion layer facing the semiconductor layer; and an oxide film containing an impurity element of the second conductivity type and formed by an atomic layer deposition method.

According to an embodiment of the present disclosure, there is provided a method of manufacturing a solid-state image pickup device, the method including: forming a semiconductor layer of a first conductivity type for each pixel in a semiconductor substrate; forming an oxide film containing an impurity element of a second conductivity type on the semiconductor substrate by an atomic layer deposition method; and forming a solid-phase diffusion layer of the second conductivity type in a surface portion of the semiconductor substrate, the solid-phase diffusion layer facing the semiconductor layer.

According to an embodiment of the present disclosure, there is provided an electronic apparatus with a solid-state image pickup device, the solid-state image pickup device including: a semiconductor substrate; a semiconductor layer of a first conductivity type formed in the semiconductor substrate and formed for each pixel; a solid-phase diffusion layer of a second conductivity type formed in a surface portion of the semiconductor substrate, the solid-phase diffusion layer facing the semiconductor layer; and an oxide film containing an impurity element of the second conductivity type and formed by an atomic layer deposition method.

In the solid-state image pickup device and the electronic apparatus according to the above-described respective embodiments of the present disclosure, the provision of the oxide film that is formed on the semiconductor substrate having the semiconductor layer of the first conductivity type by the atomic layer deposition method and contains the impurity element of the second conductivity type allows to carry out solid-phase diffusion with a low dose amount of the impurity element from the oxide film in a manufacturing process. It is possible to form the solid-phase diffusion layer of the second conductivity type in the surface portion of the semiconductor substrate with a desirable concentration distribution.

In the method of manufacturing the solid-state image pickup device according to the above-described embodiment of the present disclosure, the formation of the oxide film containing the impurity element of the second conductivity type on the semiconductor substrate having the semiconductor layer of the first conductivity type by the atomic layer deposition method allows to carry out solid-phase diffusion with a low dose amount of the impurity element from the oxide film, thereby forming the solid-phase diffusion layer of the second conductivity type. It is possible to form the solid-phase diffusion layer of the second conductivity type in the surface portion of the semiconductor substrate with a desirable concentration distribution.

According to the solid-state image pickup device and the electronic apparatus of the above-described respective embodiments of the present disclosure, there is provided the oxide film that is formed on the semiconductor substrate having the semiconductor layer of the first conductivity type by the atomic layer deposition method and contains the impurity element of the second conductivity type. This allows to form the solid-phase diffusion layer of the second conductivity type in the surface portion of the semiconductor substrate with a desirable concentration distribution. As a result, this makes it possible to form the HAD structure for suppressing occurrence of dark current.

According to the method of manufacturing the solid-state image pickup device of the above-described embodiment of the present disclosure, the formation of the oxide film containing the impurity element of the second conductivity type on the semiconductor substrate having the semiconductor layer of the first conductivity type by the atomic layer deposition method allows to form the solid-phase diffusion layer of the second conductivity type in the surface portion of the semiconductor substrate with a desirable concentration distribution. As a result, this makes it possible to form the HAD structure for suppressing occurrence of dark current.

It is to be understood that both the foregoing general description and the following detailed description are exemplary, and are intended to provide further explanation of the technology as claimed.

### BRIEF DESCRIPTION OF THE DRAWINGS

The accompanying drawings are included to provide a further understanding of the present disclosure, and are incorporated in and constitute a part of this specification. The drawings illustrate embodiments and, together with the specification, serve to explain the principles of the present technology.

FIG. 1 is a cross-sectional schematic diagram showing a simplified configuration of a solid-state image pickup device according to an embodiment of the present disclosure.

FIG. 2 is a cross-sectional schematic diagram for explaining a method of manufacturing the solid-state image pickup device illustrated in FIG. 1.

FIG. 3 is a cross-sectional schematic diagram showing a process following on a process shown in FIG. 2.

FIG. 4 is a cross-sectional schematic diagram showing a process following on the process shown in FIG. 3.

FIG. 5A is a cross-sectional schematic diagram showing a process following on the process shown in FIG. 4.

FIG. 5B is a cross-sectional schematic diagram showing a process following on the process shown in FIG. 5A.

FIG. 6 is a cross-sectional schematic diagram showing a process following on the process shown in FIG. 5B.

FIG. 7A is a cross-sectional schematic diagram showing a process following on the process shown in FIG. 6.

FIG. 7B is a cross-sectional schematic diagram showing a process following on the process shown in FIG. 7A.

FIG. 8 is a cross-sectional schematic diagram showing a process following on the process shown in FIG. 7B.

FIG. 9A is a cross-sectional schematic diagram for explaining a method of manufacturing a solid-state image pickup device according to Modification example 1.

FIG. 9B is a cross-sectional schematic diagram showing a process following on a process shown in FIG. 9A.

FIG. 10 is a cross-sectional schematic diagram showing a process following on the process shown in FIG. 9B.

FIG. 11 is a cross-sectional schematic diagram showing a process following on the process shown in FIG. 10.

FIG. 12 is a cross-sectional schematic diagram showing a simplified configuration of a solid-state image pickup device according to Modification example 2.

FIG. 13 is a cross-sectional schematic diagram for explaining a method of manufacturing the solid-state image pickup device illustrated in FIG. 12.

FIG. 14 is a cross-sectional schematic diagram showing a process following on a process shown in FIG. 13.

FIG. 15 is a cross-sectional schematic diagram showing a process following on the process shown in FIG. 14.

FIG. 16A is a cross-sectional schematic diagram for explaining a method of manufacturing a solid-state image pickup device according to Modification example 3.

FIG. 16B is a cross-sectional schematic diagram showing a process following on a process shown in FIG. 16A.

FIG. 17 is a functional block diagram showing a device configuration of the solid-state image pickup device illustrated in FIG. 1.

FIG. 18 is a schematic block diagram showing a simplified configuration of an electronic apparatus using the solid-state image pickup device illustrated in FIG. 1.

### DETAILED DESCRIPTION

Hereinafter, some embodiments of the present disclosure are described in details with reference to the drawings. It is to be noted that the descriptions are provided in the order given below.

1. Embodiment (an example of a solid-state image pickup device having an HAD structure that is formed by the use of an oxide film that is formed by an atomic layer deposition method)
2. Modification Example 1 (an example of a case where a low-dose ion implantation method is used together)
3. Modification Example 2 (an example of a case where an oxide film used for solid-phase diffusion is removed and another oxide film is formed)
4. Modification Example 3 (an example of a case where the low-dose ion implantation method is used together, and an oxide film used for solid-phase diffusion is removed and another oxide film is formed)
5. Application Example 1 (an example of a device configuration for a solid-state image pickup device)
6. Application Example 2 (an example of an electronic apparatus (camera))

### Embodiment

### Configuration

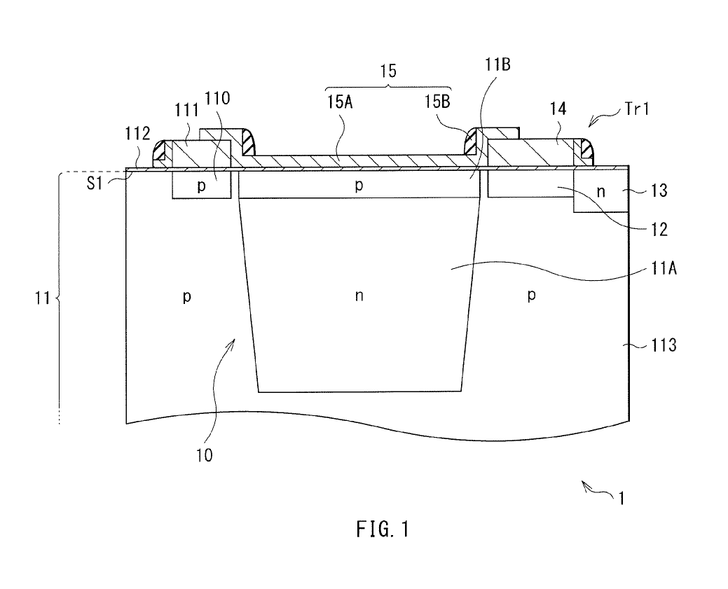

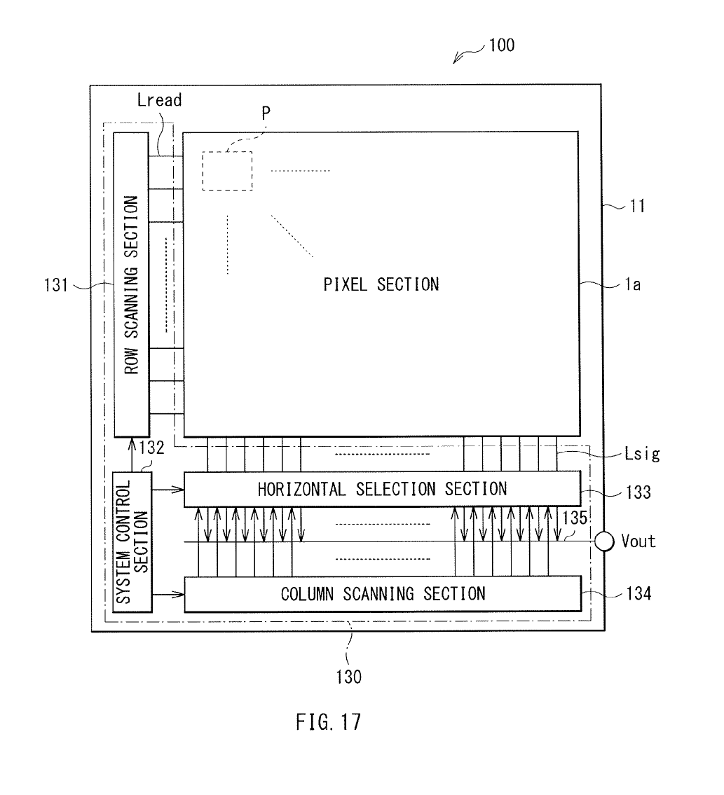

FIG. 1 schematically shows a cross-sectional configuration of a solid-state image pickup device (solid-state image pickup device 1) according to an embodiment of the present disclosure. The solid-state image pickup device 1 may be, for example, a CCD or CMOS image sensor, or the like. It is to be noted that FIG. 1 shows a region corresponding to a single pixel in a pixel section (a pixel section 1a illustrated in FIG. 17) to be hereinafter described. Further, the description is provided here by taking structure of a front face irradiation type as an example; however, a structure of a rear face irradiation type may be adopted alternatively.

In the solid-state image pickup device 1, a photodiode 10 is formed in a manner of being embedded into an n-type semiconductor substrate 11 containing silicon (Si), for example. The photodiode 10 includes an n-type impurity diffusion region (n-type semiconductor layer 11A) that may be formed on, for example, a p-type semiconductor well region 113. Within the semiconductor substrate 11, there are formed a floating diffusion (FD 13) for converting a charge generated in each of a p-type semiconductor layer 110 and the n-type semiconductor layer 11A into a voltage, and an overflow drain (OFD 12). It is to be noted that the n-type semiconductor layer 11A corresponds to a specific but not limitative example of “semiconductor layer of a first conductivity type” of the embodiment of the present disclosure.

The n-type semiconductor layer 11A may, for example, store electrons as signal charges. This n-type semiconductor layer 11A may include a p-type semiconductor region if this n-type semiconductor layer 11 includes an n-type semiconductor region as a signal charge storage region. The n-type semiconductor layer 11A may have a structure of laminating p-type and n-type semiconductor layers to form, for example, a p-n junction, a p-n-p junction, or the like.

A surface S1 (a surface on a light-receiving side) of the semiconductor substrate 11 serves as a circuit formation surface in this example, and a multilayer wiring layer that is not shown in the drawing is formed on the surface S1. Further, on the surface S1 of the semiconductor substrate 11, there are also provided a plurality of pixel transistors as driving elements for reading signal charges out of the photodiode 10. Examples of the pixel transistors may include a transfer transistor Tr 1 (TRF), a reset transistor (RST), an amplifier transistor (AMP), a selection transistor (SEL), and the like. In this drawing, only a gate (a charge transfer electrode 14) of the transfer transistor Tr 1 among those pixel transistors is illustrated. It is to be noted that, on the semiconductor substrate 11, there are provided a light-shielding layer, a color filter, an on-chip lens, and the like (which are all not shown in the drawing) with the multilayer wiring layer in between as necessary.

Each of pixel transistors such as the transfer transistor Tr1 may be, for example, a field-effect thin-film transistor (TFT). Each terminal of those pixel transistors is connected with each wiring within the multilayer wiring layer, and signal charges obtained from the photodiode 10 are output to vertical signal lines Lsig to be hereinafter described via those pixel transistors. It is to be noted that pixel transistors other than the transfer transistor Tr1 are also allowed to be shared among the pixels (for example, between the adjacent pixels).

In a configuration as described above, an impurity diffusion layer (a p-type solid-phase diffusion layer 11B) with the inverse conductivity (p-type) of that of the n-type semiconductor layer 11A is formed to face the n-type semiconductor layer 11A in a surface portion of the semiconductor substrate 11 (in the vicinity of the surface S1). A so-called HAD structure is formed of this p-type solid-phase diffusion layer 11B.

As will hereinafter be described in detail, the p-type solid-phase diffusion layer 11B is a region where, for example, boron (B) may be doped as p-type impurities utilizing a solid-phase diffusion method (using a solid impurity diffusion source). A doping concentration of the boron may be preferably controlled to be within a range of about 10¹⁷/cm³ to 10¹⁹/cm³, for example. Further, the p-type solid-phase diffusion layer 11B may be formed over a region having depth, for example, about 30 nm from the surface S1 of the semiconductor substrate 11. It is to be noted that the p-type solid-phase diffusion layer 11B corresponds to a specific but not limitative example of “solid-phase diffusion layer of a second conductivity type” of the embodiment of the present disclosure.

On the semiconductor substrate 11, there is provided a sidewall 15 with a gate oxide film 112 in between. The sidewall 15 includes an ALD-BSG film 15A and an LP-SiN film 15B, and is formed to cover a region (light-receiving region) facing the photodiode 10, as well as each side face of the charge transfer electrode 14 and a CVD oxide film 111. This sidewall 15 is for implanting n-type impurities in a self-alignment method into a region that is to serve as a source and a drain of the transfer transistor or the like.

The ALD-BSG film 15A may be formed by, for example, an atomic layer deposition method, and is a boron-containing silicon oxide film (BSG: Boron Silicate Glass). Formation by the use of the atomic layer deposition method may achieve a small interface state density and a favorable coverage as compared with other methods (such as a normal-pressure CVD method), for example. The ALD-BSG film 15A, which corresponds to a specific but not limitative example of an “oxide film” of the embodiment of the present disclosure, is used as a solid-phase diffusion source of p-type impurities in forming the p-type solid-phase diffusion layer 11B in a manufacturing process, and is utilized as a sidewall.

The LP-SiN film 15B is a silicon nitride film that may be formed using, for example, a reduced-pressure CVD (Chemical Vapor Deposition) method. In this example, the LP-SiN film 15B is laminated on a part of the ALD-BSG film 15A, and is formed to cover each side face of the charge transfer electrode 14 and the CVD oxide film 111.

### [Manufacturing Method]

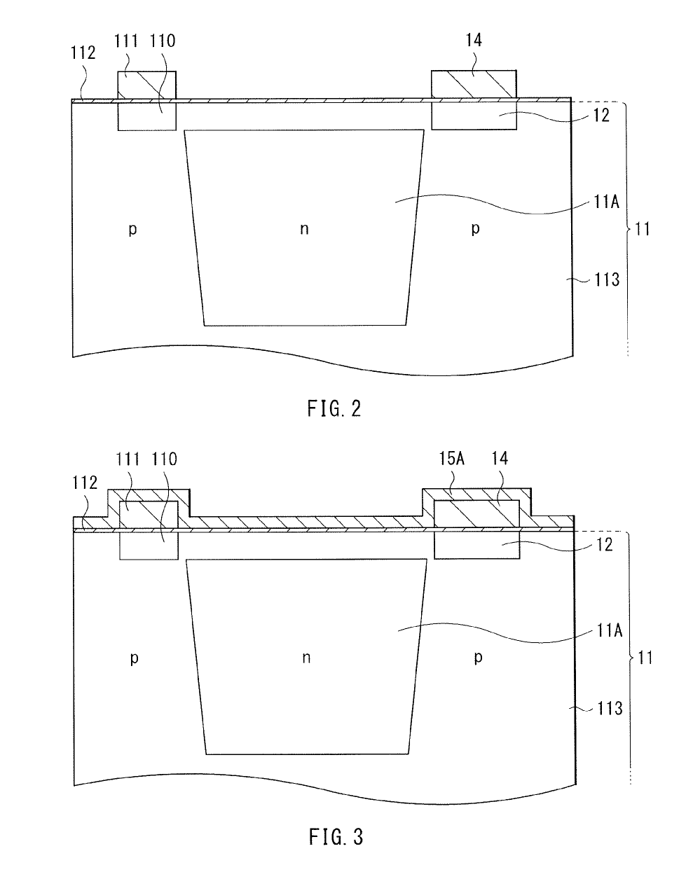

It may be possible to manufacture the solid-state image pickup device 1 as described above in the following manner, for example. Each of FIG. 2 to FIG. 7A shows a manufacturing process of the solid-state image pickup device 1. First, as shown in FIG. 2, the p-type semiconductor layer 110, the CVD oxide film 111, etc. are formed in a predetermined region of the semiconductor substrate 11 and processing is performed on the CVD oxide film 111. Further, the p-type semiconductor well region 113 is formed utilizing an ion implantation method by the use of, for example, a mask and/or the like, and thereafter the n-type semiconductor layer 11A and the OFD 12 are formed to be embedded in the p-type semiconductor well region 113. It is to be noted that, when the n-type semiconductor layer 11A is formed to have a lamination structure, for example, with a p-type semiconductor layer, the ion implantation is performed in incremental steps. Subsequently, the gate oxide film 112 is formed on the semiconductor substrate 11, and then a pattern formation of the charge transfer electrode 14 that may be configured of, for example, polysilicon is carried out.

Next, as shown in FIG. 3, the ALD-BSG film 15A is formed to cover the charge transfer electrode 14 and the CVD oxide film 111 over a whole surface of the semiconductor substrate 11 using, for example, the atomic layer deposition method. As the atomic layer deposition method, a single-substrate processing method that achieves a favorable interface state and utilizes plasma may be preferable. Use of such an atomic layer deposition method makes it possible to achieve the film formation with a small interface state density and a high coverage performance. On this occasion, a boron concentration in the ALD-BSG film 15A may be preferably controlled to be within a range of about 10¹⁹/cm³ to 10²¹/cm³, for example. It is to be noted that the concentration of the boron that is diffused into the semiconductor substrate 11 by an annealing treatment to be hereinafter described becomes lower than that in the ALD-BSG film 15A by about two or three orders of magnitude.

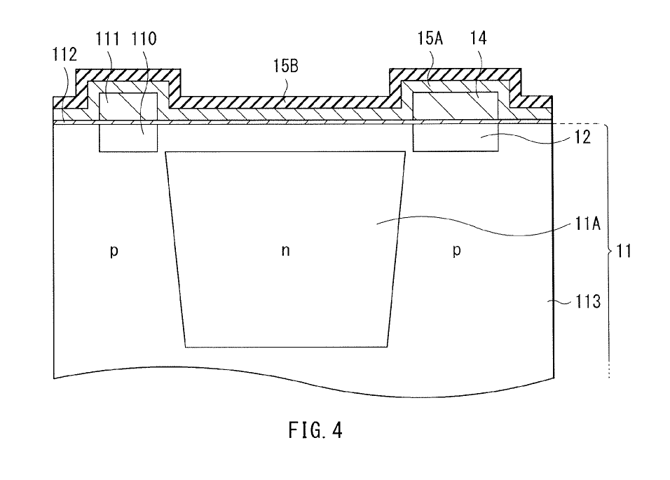

Subsequently, as shown in FIG. 4, the LP-SiN film 15B is formed on the ALD-BSG film 15A using, for example, the reduced-pressure CVD method.

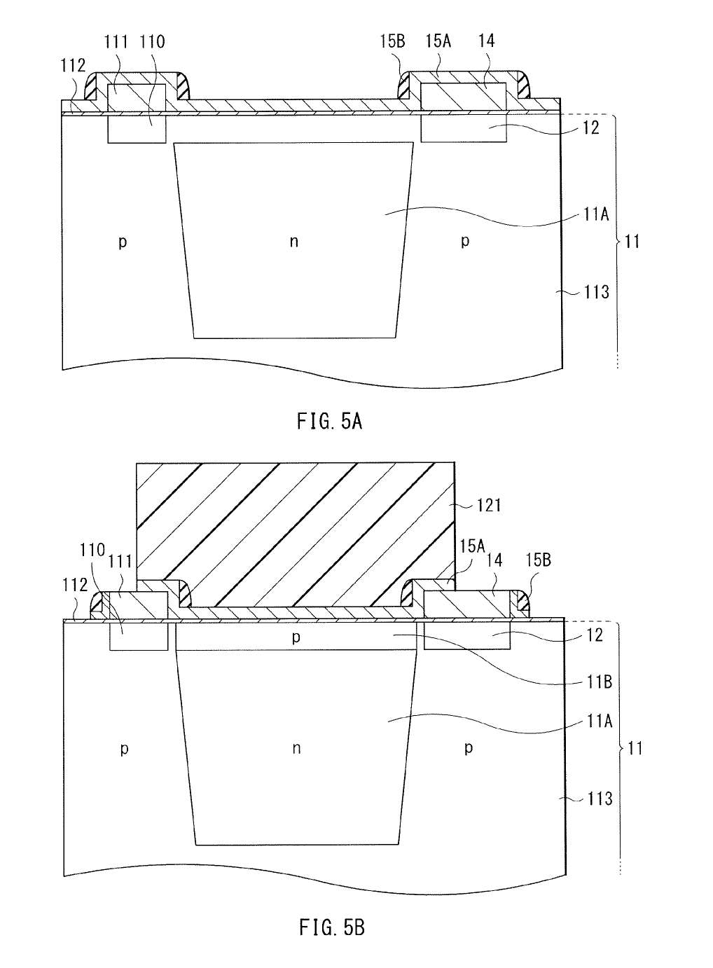

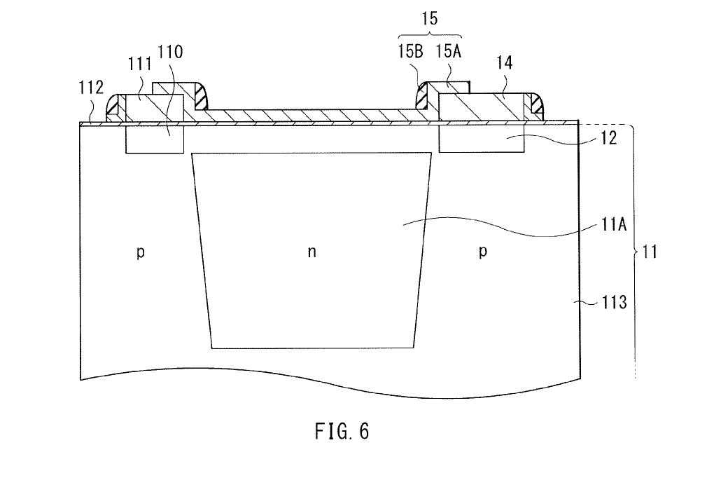

Next, as shown in FIG. 5A, the LP-SiN film 15B is etched back using, for example, a dry etching process. Afterward, as shown in FIG. 5B, a mask layer 121 may be formed to cover, for example, a photoelectric conversion region, and then the ALD-BSG film 15A is patterned by a dry etching or wet etching process, for example. On this occasion, the patterning is carried out to allow a part of the surfaces of the charge transfer electrode 14 and the CVD oxide film 111 is exposed. Thereafter, as shown in FIG. 6, the mask layer 121 is peeled off. In such a manner, the sidewall 15 is formed.

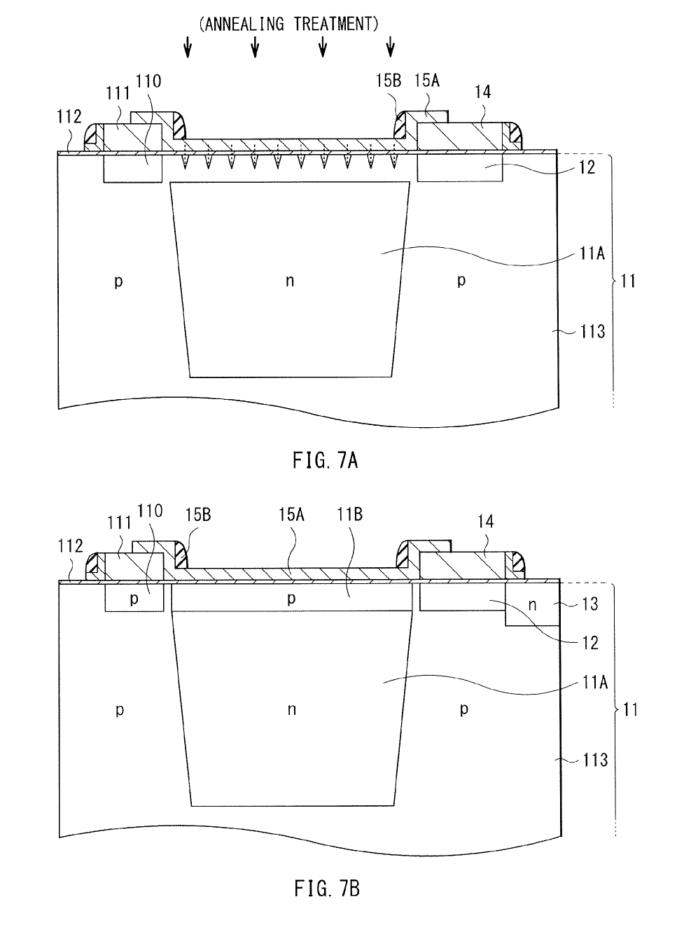

Thereafter, as shown in FIG. 7A, the annealing treatment is carried out to perform a solid-phase diffusion of the boron contained in the ALD-BSG film 15A in the surface portion of the semiconductor substrate 11 using the ALD-BSG film 15A as a solid-phase diffusion source. Examples of the annealing treatment may include a thermal treatment using a batch furnace, an RTA (Rapid Thermal Anneal) adopting a single-substrate processing method, or the like. It is to be noted that, for a batch processing, a thermal treatment may be preferably performed for about one to four hours at temperature within a range of about 300 degrees centigrade to 500 degrees centigrade in a nitrogen (N₂) gas atmosphere, for example. For the RTA, a thermal treatment may be preferably performed for about five to ten minutes at temperature within a range of about 800 degrees centigrade to 1050 degrees centigrade in a nitrogen gas atmosphere, for example.

In the above-described manner, as shown in FIG. 7B, the p-type solid-phase diffusion layer 11B is formed in the surface portion of the semiconductor substrate 11. Further, impurity concentration of the p-type solid-phase diffusion layer 11B is controlled depending on the boron concentration in the ALD-BSG film 15A that is formed using the atomic layer deposition method and is controlled by means of the annealing treatment. For example, as mentioned previously, the impurity concentration of the p-type solid-phase diffusion layer 113 may be controlled to be within a range of about 10¹⁷/cm³ to 10¹⁹/cm³.

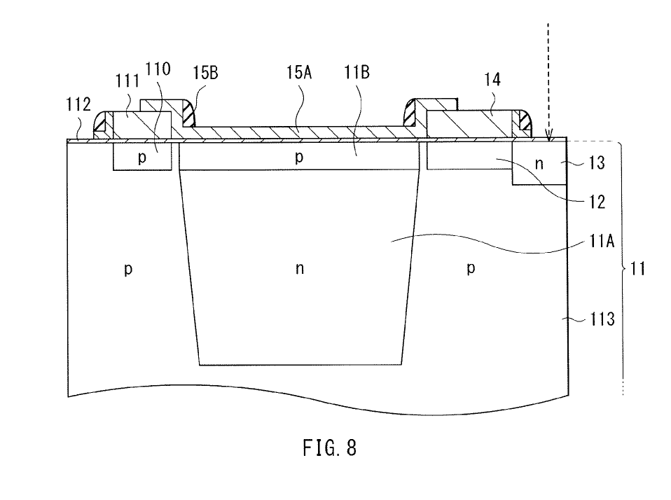

Afterward, as shown in FIG. 8, the FD 13 is formed in a predetermined region of the semiconductor substrate 11 by the ion implantation method using a mask.

Finally, after formation of a multilayer wiring layer, the semiconductor substrate 11 is ground to attain a desirable thickness, and the color filter, the on-chip lens, and/or the like are formed on the multilayer wiring layer as necessary. The steps described thus far will complete the solid-state image pickup device illustrated in FIG. 1.

In this embodiment of the present disclosure, as described above, in a manufacturing process, the ALD-BSG film 15A is formed on the semiconductor substrate 11, and the annealing treatment is carried out using this ALD-BSG film 15A as a solid-phase diffusion source. This makes it possible to form the p-type solid-phase diffusion layer 11B in the surface portion of the semiconductor substrate 11. In other words, this allows the HAD structure to be formed. As a result, this makes it possible to recombine electrons generated in an interface state in the vicinity of an interface of silicon with holes, which suppresses occurrence of dark current that is caused by such an interface state.

On this occasion, use of the ALD-BSG film 15A that is formed using the atomic layer deposition method as a solid-phase diffusion source facilitates a control with a low dose amount as described above in comparison with a case of using an oxide film that is formed using, for example, a normal-pressure CVD method. Further, such a manner suppresses spreading in the impurity concentration distribution in a depth direction within the semiconductor substrate 11 and makes it easier to form the desirable impurity concentration distribution in the p-type solid-phase diffusion layer 11B (a profile in a depth direction is formed more sharply.)

Accordingly, this makes it possible to form the p-type solid-phase diffusion layer 11B in a shallower region in the surface portion of the semiconductor substrate 11, which facilitates to assure a larger region for formation of the n-type semiconductor layer 11A that is formed on a lower layer of the p-type solid-phase diffusion layer 11B. Further, since charges stored on the n-type semiconductor layer 11A are transferred to the FD 13 following a path along the surface S1 of the semiconductor substrate 11 during a readout operation, a greater thickness of the p-type solid-phase diffusion layer 11B (formation of the p-type solid-phase diffusion layer 11B into a deep region) would make it easy to form a barrier against the signal charges (for example, electrons). As described above, it is possible to form the p-type solid-phase diffusion layer 11B in a shallower region, which reduces a region to serve as a barrier in a transmission path of signal charges, and thereby, occurrence of leakage current is suppressed.

Further, use of the solid-phase diffusion method allows occurrence of silicon crystalline defect to be reduced as compared with a case of using the ion implantation method, which makes it possible to suppress occurrence of dark current that is caused by such a crystalline defect. Additionally, for the ion implantation method, in accordance with reduction in the pixel size, the multiple-stage ion implantation may be preferably carried out while changing a location or a direction that is subjected to the ion implantation. As a result, this may often increase the number of ion implantation steps, although a method of using the atomic layer deposition method and the annealing treatment as in this embodiment of the present disclosure allows p-type impurities to be diffused without increasing the number of steps even if the pixel size is reduced.

Moreover, the ALD-BSG film 15A that is used as a solid-phase diffusion source is formed using the atomic layer deposition method, which achieves a small interface state density and a favorable coverage performance. Consequently, it is possible to still leave the ALD-BSG film 15A on the semiconductor substrate 11 even after it is used as a solid-phase diffusion source and to use the ALD-BSG film 15A as a sidewall (a sidewall 15). For example, with a BSG film that is formed using the normal-pressure CVD method, it may be difficult to use such a film as a sidewall due to inadequate interface state and inadequate coverage performance thereof.

It is to be noted that a laminated film of an HTO (High Temperature Oxide) film and the LP-SiN film as described above may be typically used as a sidewall in many cases. The sidewall 15 using the ALD-BSG film 15A is capable of achieving the performance (performance as a sidewall) comparable to such a laminated film using the HTO film.

As described thus far, in the solid-state image pickup device 1 according to this embodiment of the present disclosure, there is provided the ALD-BSG film 15A that is formed on the semiconductor substrate 11 having the n-type semiconductor layer 11A using the atomic layer deposition method and contains the p-type impurity element (boron). This allows carrying out solid-phase diffusion with a low dose amount of the impurity element from the ALD-BSG film 15A in a manufacturing process. This makes it possible to form the p-type solid-phase diffusion layer 11B in the surface portion of the semiconductor substrate 11, with a desirable concentration distribution. As a result, it is possible to form the HAD structure for suppressing occurrence of dark current.

Next, the description is provided on modification examples (Modification examples 1 to 3) of the solid-state image pickup device 1 according to the above-described embodiment of the present disclosure. Hereinafter, component parts substantially the same as those in the above-described embodiment are denoted with the same reference numerals, and the related descriptions are omitted as appropriate.

### Modification Example 1

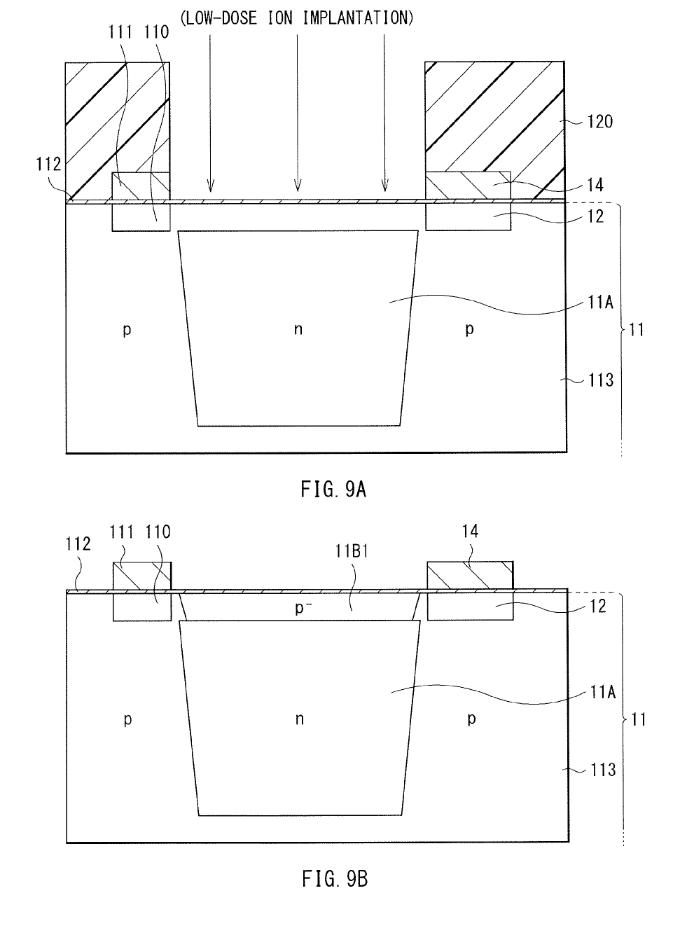

Each of FIG. 9A to FIG. 11 schematically shows a cross-sectional configuration for explaining a method of manufacturing a solid-state image pickup device according to Modification example 1. In the above-described embodiment of the present disclosure, the p-type solid-phase diffusion layer 11B is formed in the surface portion of the semiconductor substrate 11 by the use of only the solid-phase diffusion method utilizing the ALD-BSG film 15A and the annealing treatment. However, a low-dose ion implantation may be implemented beforehand in the surface portion of the semiconductor substrate 11 like this modification example.

More specifically, to start with, the charge transfer electrode 14 and the like are formed on the semiconductor substrate 11 on which the n-type semiconductor layer 11A is formed, and then a mask layer 120 is formed on the semiconductor substrate 11 as illustrated in FIG. 9A. Using this mask layer 120, the p-type impurity (boron) is diffused into the surface portion of the semiconductor substrate 11 utilizing the low-dose ion implantation. A dose amount may be, for example, within a range of about 10¹²/cm² to 10¹³/cm². In such a manner, as shown in FIG. 9B, a low-concentration p-type impurity diffusion layer 11B1 is formed in the surface portion of the semiconductor substrate 11.

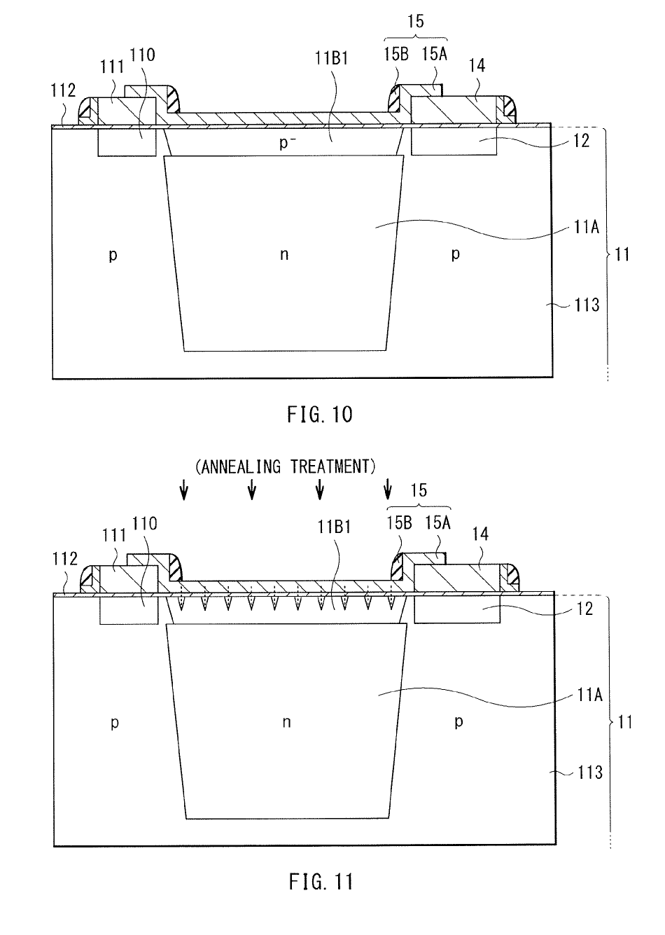

Subsequently, as shown in FIG. 10, as with the above-described embodiment of the present disclosure, the sidewall 15 that is configured of the ALD-BSG film 15A and the LP-SiN film 15B is formed on the semiconductor substrate 11. Thereafter, as shown in FIG. 11, as with the above-described embodiment of the present disclosure, the p-type solid-phase diffusion layer 11B is formed by performing the annealing treatment. The following steps are the same as those of the above-described embodiment of the present disclosure.

In such a manner, the HAD structure may be formed by the combined use of the low-dose ion implantation method and the solid-phase diffusion method. Even in such a case, it is possible to obtain the advantageous effects almost equivalent to those of the above-described embodiment of the present disclosure.

### Modification Example 2

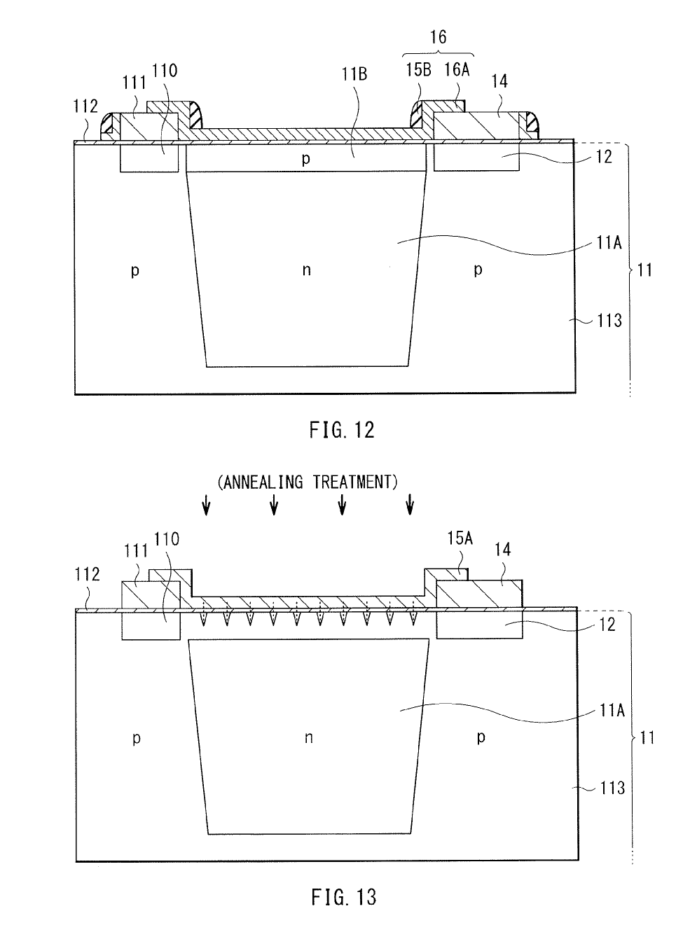

FIG. 12 schematically shows a cross-sectional configuration of a solid-state image pickup device according to Modification example 2. In this modification example, as with the above-described embodiment of the present disclosure, the p-type solid-phase diffusion layer 11B is formed in the solid-phase diffusion method using the ALD-BSG film 15A. However, Modification example 2 is different from the above-described embodiment of the present disclosure in that the ALD-BSG film 15A is removed after the solid-phase diffusion is completed. The solid-state image pickup device according to this modification example has an HTO film 16A as a sidewall 16 instead of the above-described ALD-BSG film 15A. The sidewall 16 has the HTO film 16A and the LP-SiN film 15B.

It may be possible to manufacture such a solid-state image pickup device in the following manner, for example. In other words, to start with, as shown in FIG. 13, as with the above-described embodiment of the present disclosure, the ALD-BSG film 15A is formed, and then a patterning thereof is performed. Subsequently, a solid-phase diffusion of boron is carried out from the ALD-BSG film 15A by performing a predetermined annealing treatment.

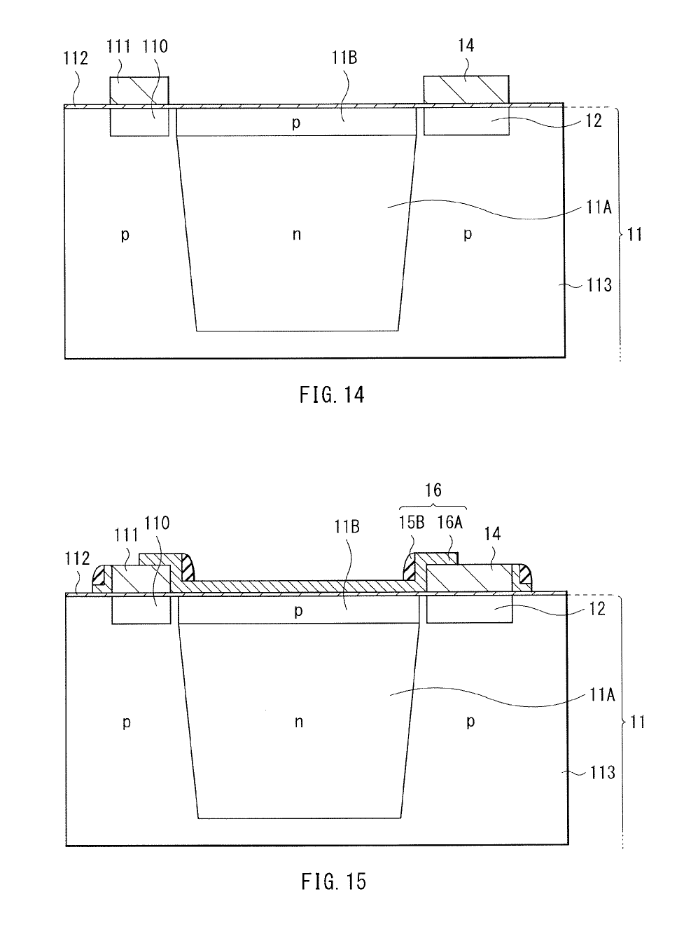

Thereafter, in this modification example, as shown in FIG. 14, the ALD-BSG film 15A is removed from the semiconductor substrate 11 by performing wet etching using, for example, DHF (dilute fluoric acid). Subsequently, as shown in FIG. 15, the sidewall 16 is formed in such a manner that the HTO film 16A and the LP-SiN film 15B are formed and processed using, for example, an LP-CVD method and the like.

Like this modification example, the ALD-BSG film 15A may be removed after the ALD-BSG film 15A is used for the solid-phase diffusion, and then may be replaced with another oxide film (for example, the HTO film 16A). Even in such a case, it is possible to obtain the advantageous effects almost equivalent to those of the above-described embodiment of the present disclosure.

### Modification Example 3

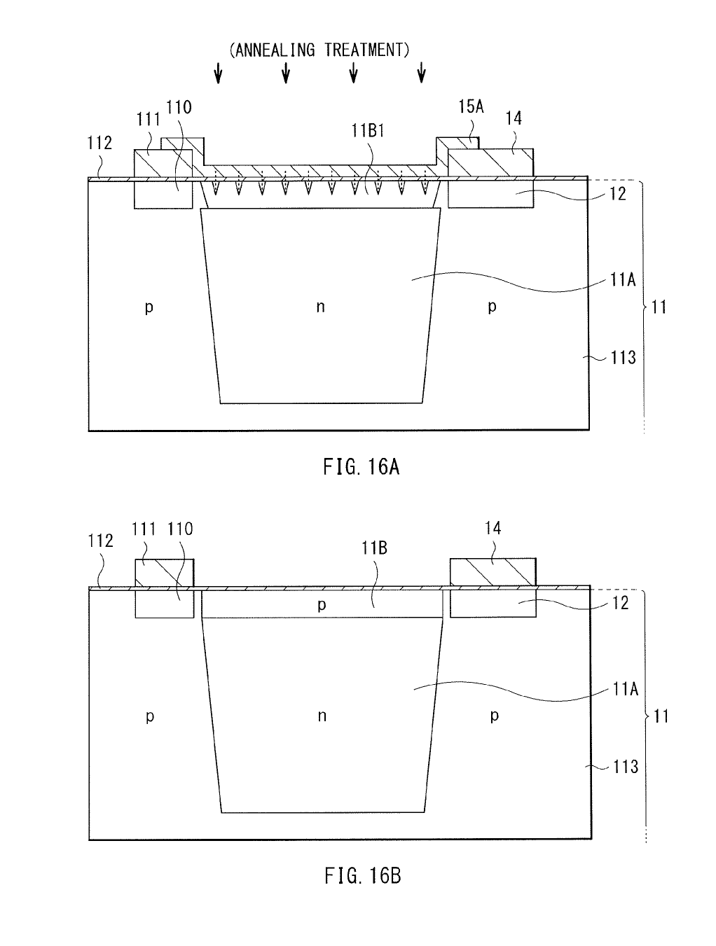

Each of FIG. 16A and FIG. 16B schematically shows a cross-sectional configuration for explaining a method of manufacturing a solid-state image pickup device according to Modification example 3. Like this modification example, a method of the above-described Modification example 1 (method of using the low-dope ion implantation method and the solid-phase diffusion method in combination) may be used in combination with a method of the above-described Modification example 2 (method of removing the ALD-BSG film 15A to form another oxide film instead). In other words, as shown in FIG. 16A, as with the above-described Modification example 1, the low-concentration p-type impurity diffusion layer 11B1 is formed beforehand in the surface portion of the semiconductor substrate 11 by the low-dope ion implantation method, and the solid-phase diffusion of the p-type impurity (boron) is further carried out by performing the annealing treatment using the ALD-BSG film 15A. After the p-type solid-phase diffusion layer 11B is formed in such a manner, the ALD-BSG film 15A is removed as shown in FIG. 16B, as with the above-described Modification example 2. Thereafter, the HTO film 16A and the LP-SiN film 15B are formed, and thereby, the sidewall 16 is formed.

### Application Example 1

FIG. 17 shows an overall configuration of a unit in which any of the solid-state image pickup devices that are described in the above-described embodiment, Modification examples 1 to 3 of the present disclosure, and the like is used for each pixel. Each of these solid-state image pickup units (hereinafter to be described by taking the solid-state image pickup unit 100 as an example) has a pixel section 1a as an image pickup area, as well as a peripheral circuit section 130 that may be composed of, for example, a row scanning section 131, a horizontal selection section 133, a column scanning section 134, and a system control section 132 in a peripheral region of the pixel section 1a.

The pixel section 1a has a plurality of unit pixels P (corresponding to the solid-state image pickup devices 1) that may be arranged two-dimensionally in a matrix pattern, for example. A pixel driving line Lread (more specifically, a row selection line and a reset control line) may be wired to the unit pixels P for each row of the pixels, for example, and a vertical signal line Lsig may be wired to the unit pixels P for each column of the pixels. The pixel driving line Lread is configured to transmit a drive signal for reading signals out of the pixels. One end of the pixel driving line Lread is connected with an output end corresponding to each row of the row scanning section 131.

The row scanning section 131, which is configured of a shift register, an address decoder, and the like, is a pixel driving section that drives each of the pixels P within the pixel section 1a on each row basis, for example. A signal to be output from each of the pixels P in a pixel row that is selectively scanned by the row scanning section 131 is delivered to the horizontal selection section 133 through each of the vertical signal lines Lsig. The horizontal selection section 133 is configured of an amplifier, a horizontal selection switch, and the like that are provided for each of the vertical signal lines Lsig.

The column scanning section 134, which is configured of a shift register, an address decoder, and the like, sequentially drives each of the horizontal selection switches within the horizontal selection section 133 while scanning each of the horizontal selection switches. Through such a selective scanning that is performed by the column scanning section 134, signals for the respective pixels to be transmitted via the respective vertical signal lines Lsig are output in sequence to horizontal signal lines 135, and are transmitted to the outside of the substrate 11 through the horizontal signal lines 135.

The circuit section that is configured of the row scanning section 131, the horizontal selection section 133, the column scanning section 134, and the horizontal signal lines 135 may be formed directly on the substrate 11, or may be mounted on an external control IC. Alternatively, such a circuit section may be formed on another substrate that is connected to the pixel section 1a by means of a cable and/or the like.

The system control section 132 receives a clock signal to be applied from the outside, data for commanding an operating mode, and/or the like, and outputs data such as internal information on the solid-state image pickup device 1. Further, the system control section 132 has a timing generator that generates various timing signals to perform drive control of the peripheral circuit such as the row scanning section 131, the horizontal selection section 133, the column scanning section 134, and the like, based on various timing signals that are generated by the timing generator.

### Application Example 2

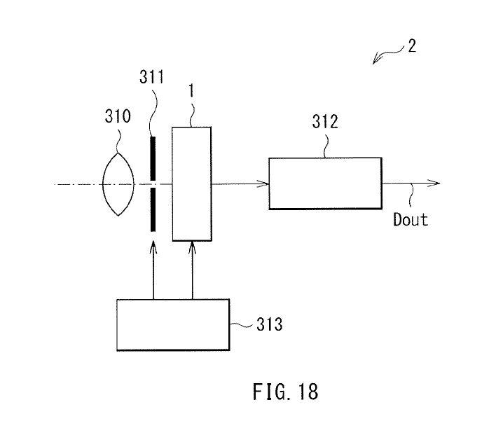

The above-described solid-state image pickup unit 100 is applicable to various types of electronic apparatuses with an image pickup function, for example, a camera system such as a digital still camera and a video camera, a cellular phone with an image pickup function, etc. As an example, FIG. 18 shows a simplified configuration of an electronic apparatus 3 (camera). The electronic apparatus 3, which is a video camera capable of shooting, for example, still images or moving images, has the solid-state image pickup unit 100, an optical system (optical lens) 310, a shutter device 311, a driving section 313 that drives the solid-state image pickup unit 100 and the shutter device 311, and a signal processing section 312.

The optical system 310 guides image light (incident light) from a subject to the pixel section 1a on the solid-state image pickup unit 100. The optical system 310 may be configured of a plurality of optical lenses. The shutter device 311 controls a period of light irradiation to the solid-state image pickup unit 100 and a light-shielding period. The driving section 313 controls a transfer operation of the solid-state image pickup unit 100 and a shutter operation of the shutter device 311. The signal processing section 312 performs various types of signal processing on signals output from the solid-state image pickup unit 100. An image signal Dout on which the signal processing has been performed is stored in a storage medium such as a memory, or is output to a monitor or the like.

The present disclosure is described thus far with reference to the embodiment and modification examples thereof. However, the present disclosure is not limited to the above-described embodiment and the like, and may be variously modified. For example, in the above-described embodiment and the like, the description is provided by taking, as an example, the solid-state image pickup device of the front face irradiation type. However, the solid-state image pickup device according to the embodiment of the present disclosure is applicable to a solid-state image pickup device of a rear face irradiation type as well. Further, in the case of the rear face irradiation type, the embodiment of the present disclosure is also applicable to a so-called lengthwise spectroscopic solid-state image pickup device in which a photoelectric converter device using an organic photoelectric conversion film on the semiconductor substrate 11.

Further, in the above-described embodiment and the like, the n-type semiconductor layer 11A is exemplified as the first conductivity type semiconductor layer of the embodiment of the present disclosure. However, this is not limitative, and a p-type semiconductor layer may be used. In this case, an n-type solid-phase diffusion layer may be formed in the surface portion of the semiconductor substrate 11.

It is possible to achieve at least the following configurations from the above-described example embodiments and the modifications of the disclosure.

(1) A solid-state image pickup device, including:

a semiconductor substrate;

a semiconductor layer of a first conductivity type formed in the semiconductor substrate and formed for each pixel;

a solid-phase diffusion layer of a second conductivity type formed in a surface portion of the semiconductor substrate, the solid-phase diffusion layer facing the semiconductor layer; and

an oxide film containing an impurity element of the second conductivity type and formed by an atomic layer deposition method.

(2) The solid-state image pickup device according to (1), further including:

a photodiode in the semiconductor substrate, the photodiode including the semiconductor layer; and

a pixel transistor configured to read out a signal charge from the photodiode.

(3) The solid-state image pickup device according to (2), further including

a charge transfer electrode on the semiconductor substrate, the charge transfer electrode being configured to transfer a charge generated in the semiconductor layer, wherein

the oxide film covers a side face of the charge transfer electrode.

(4) The solid-state image pickup device according to (2) or (3), wherein the oxide film serves as a sidewall.
(5) The solid-state image pickup device according to any one of (1) to (4), wherein the first conductivity type is an n-type, and the second conductivity type is a p-type.
(6) The solid-state image pickup device according to any one of (1) to (4), wherein the oxide film is a silicon oxide film containing boron (B).
(7) The solid-state image pickup device according to (6), wherein a silicon nitride film is laminated on part or all of the oxide film.
(8) A method of manufacturing a solid-state image pickup device, the method including:

forming a semiconductor layer of a first conductivity type for each pixel in a semiconductor substrate;

forming an oxide film containing an impurity element of a second conductivity type on the semiconductor substrate by an atomic layer deposition method; and

forming a solid-phase diffusion layer of the second conductivity type in a surface portion of the semiconductor substrate, the solid-phase diffusion layer facing the semiconductor layer.

(9) The method according to (8), wherein solid-phase diffusion of the impurity element is carried out on the surface portion of the semiconductor substrate from the oxide film by performing an annealing treatment in the forming of the solid-phase diffusion layer.
(10) The method according to (9), wherein low-dose ion implantation of the impurity element of the second conductivity type is performed in the surface portion of the semiconductor substrate prior to the annealing treatment.
(11) The method according to any one of (8) to (10), further including:

after the forming of the solid-phase diffusion layer,

removing the oxide film; and

forming another oxide film on the semiconductor substrate.

(12) The method according to any one of (8) to (11), wherein the first conductivity type is an n-type, and the second conductivity type is a p-type.
(13) The method according to any one of (8) to (12), wherein the oxide film is a silicon oxide film containing boron (B).
(14) An electronic apparatus with a solid-state image pickup device, the solid-state image pickup device including:

a semiconductor substrate;

a semiconductor layer of a first conductivity type formed in the semiconductor substrate and formed for each pixel;

a solid-phase diffusion layer of a second conductivity type formed in a surface portion of the semiconductor substrate, the solid-phase diffusion layer facing the semiconductor layer; and

an oxide film containing an impurity element of the second conductivity type and formed by an atomic layer deposition method.

It should be understood by those skilled in the art that various modifications, combinations, sub-combinations and alterations may occur depending on design requirements and other factors insofar as they are within the scope of the appended claims or the equivalents thereof.

What is claimed is:

1. A solid-state image pickup device, comprising:
a semiconductor substrate;
a semiconductor layer of a first conductivity type formed in the semiconductor substrate and formed for each pixel;
a solid-phase diffusion layer of a second conductivity type formed in a surface portion of the semiconductor substrate, the solid-phase diffusion layer facing the semiconductor layer; and
an oxide film containing an impurity element of the second conductivity type and formed by an atomic layer deposition method.

2. The solid-state image pickup device according to claim 1, further comprising:
a photodiode in the semiconductor substrate, the photodiode including the semiconductor layer; and
a pixel transistor configured to read out a signal charge from the photodiode.

3. The solid-state image pickup device according to claim 2, further comprising
a charge transfer electrode on the semiconductor substrate, the charge transfer electrode being configured to transfer a charge generated in the semiconductor layer, wherein
the oxide film covers a side face of the charge transfer electrode.

4. The solid-state image pickup device according to claim 2, wherein the oxide film serves as a sidewall.

5. The solid-state image pickup device according to claim 1, wherein the first conductivity type is an n-type, and the second conductivity type is a p-type.

6. The solid-state image pickup device according to claim 1, wherein the oxide film is a silicon oxide film containing boron (B).

7. The solid-state image pickup device according to claim 6, wherein a silicon nitride film is laminated on part or all of the oxide film.

8. A method of manufacturing a solid-state image pickup device, the method comprising:
forming a semiconductor layer of a first conductivity type for each pixel in a semiconductor substrate;
forming an oxide film containing an impurity element of a second conductivity type on the semiconductor substrate by an atomic layer deposition method; and
forming a solid-phase diffusion layer of the second conductivity type in a surface portion of the semiconductor substrate, the solid-phase diffusion layer facing the semiconductor layer.

9. The method according to claim 8, wherein solid-phase diffusion of the impurity element is carried out on the surface portion of the semiconductor substrate from the oxide film by performing an annealing treatment in the forming of the solid-phase diffusion layer.

10. The method according to claim 9, wherein low-dose ion implantation of the impurity element of the second conductivity type is performed in the surface portion of the semiconductor substrate prior to the annealing treatment.

11. The method according to claim 8, further comprising:
after the forming of the solid-phase diffusion layer,
removing the oxide film; and
forming another oxide film on the semiconductor substrate.

12. The method according to claim 8, wherein the first conductivity type is an n-type, and the second conductivity type is a p-type.

13. The method according to claim 8, wherein the oxide film is a silicon oxide film containing boron (B).

14. An electronic apparatus with a solid-state image pickup device, the solid-state image pickup device comprising:
a semiconductor substrate;
a semiconductor layer of a first conductivity type formed in the semiconductor substrate and formed for each pixel;
a solid-phase diffusion layer of a second conductivity type formed in a surface portion of the semiconductor substrate, the solid-phase diffusion layer facing the semiconductor layer; and
an oxide film containing an impurity element of the second conductivity type and formed by an atomic layer deposition method.
